(19) United States
(12) Patent Application Publication
(10) Pub. No.: US 2025/0096584 A1
(43) Pub. Date: Mar. 20, 2025

(54) INLET AND CHARGER HAVING THE SAME

(71) Applicant: LITE-ON TECHNOLOGY CORPORATION, Taipei (TW)

(72) Inventors: Chen-Yu TSAI, Taipei (TW); Yu-Po Chen, Taipei (TW)

(21) Appl. No.: 18/407,487

(22) Filed: Jan. 9, 2024

(30) Foreign Application Priority Data
Sep. 14, 2023 (CN) 202311184583.3

(51) Int. Cl. H02J 7/00; H01R 13/46; H01R 13/66

(52) U.S. Cl. CPC H02J 7/0042; H01R 13/6658; H01R 13/46

(57) ABSTRACT

An inlet for a charger is provided. The inlet includes a body, a first plate, a circuit board assembly, and a second plate. The first plate is disposed on the body. The first plate has a first hole. The circuit board assembly is disposed on the first plate. The circuit board assembly has a second hole. The second plate is disposed on the circuit board assembly. The body has a first pin. The first pin penetrates through the first hole and the second hole and is covered by the second plate.

This application claims the benefit of People's Republic of China application Serial No. 202311184583.3, filed on Sep. 14, 2023, the subject matter of which is incorporated herein by reference.

### TECHNICAL FIELD

This disclosure relates to an inlet and a charger having the same.

### BACKGROUND

As computers, communication, and consumer electronics become more and more popular, and more and more accessories thereof become needed to be charged, chargers have been widely used. In a typical charger, a main printed circuit board (PCB) assembly has one high voltage region and two low voltage regions. The low voltage regions are located at two sides of the high voltage region, and are electrically coupled through a jump wire. Since each low voltage region is required to be separated from the high voltage region by a safe distance, it is hard to further reduce the size of the charger.

### SUMMARY

This disclosure is directed to a means to further reduce the size of a charger.

According to some embodiments, an inlet for a charger is provided. The inlet comprises a body, a first plate, a circuit board assembly, and a second plate. The first plate is disposed on the body. The first plate has a first hole. The circuit board assembly is disposed on the first plate. The circuit board assembly has a second hole. The second plate is disposed on the circuit board assembly. The body has a first pin penetrating through the first hole and the second hole and covered by the second plate.

According to some embodiments, a charger is provided. The charger comprises a charging plug. The charging plug comprises a housing, a main circuit board assembly, and an inlet. The housing has an inlet opening. The main circuit board assembly is disposed in the housing. The inlet is disposed at the inlet opening. The inlet comprises a body, a first plate, a circuit board assembly, and a second plate. The first plate is disposed on the body. The first plate has a first hole. The circuit board assembly is disposed on the first plate. The circuit board assembly has a second hole. The second plate is disposed on the circuit board assembly. The body has a first pin. The first pin penetrates through the first hole and the second hole and is covered by the second plate.

### BRIEF DESCRIPTION OF THE DRAWINGS

FIGS. 1A-1H show an exemplary inlet of the disclosure.

FIGS. 2A-2C show an exemplary charger of the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

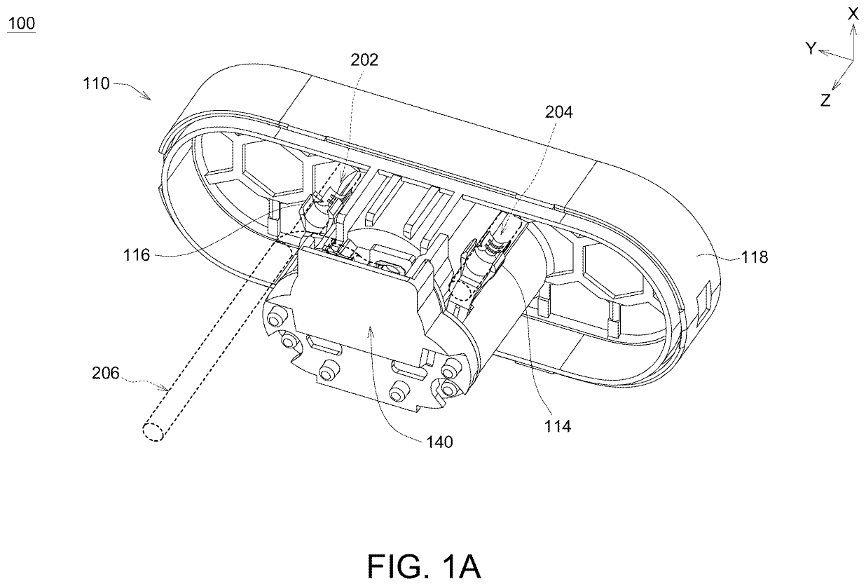

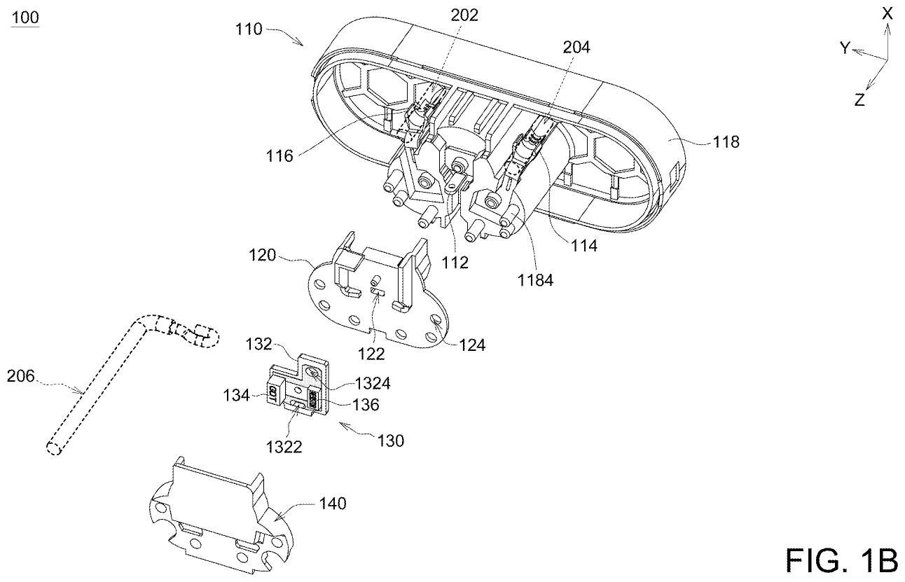

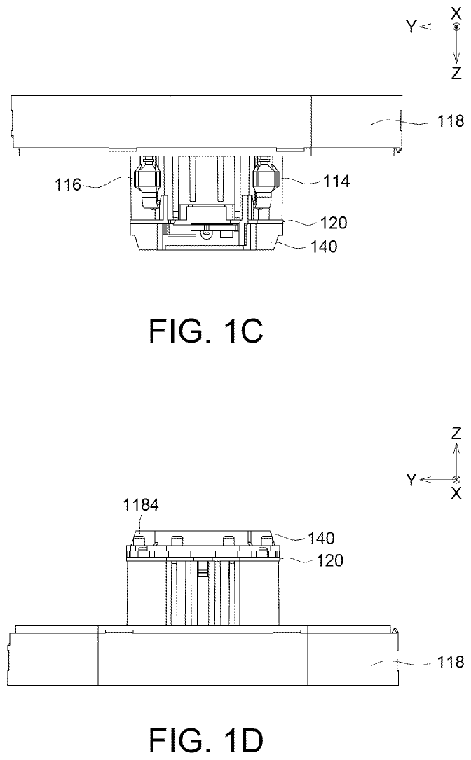

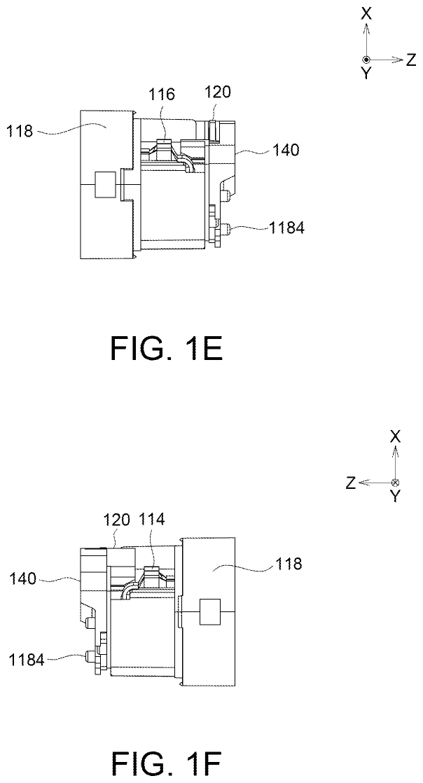

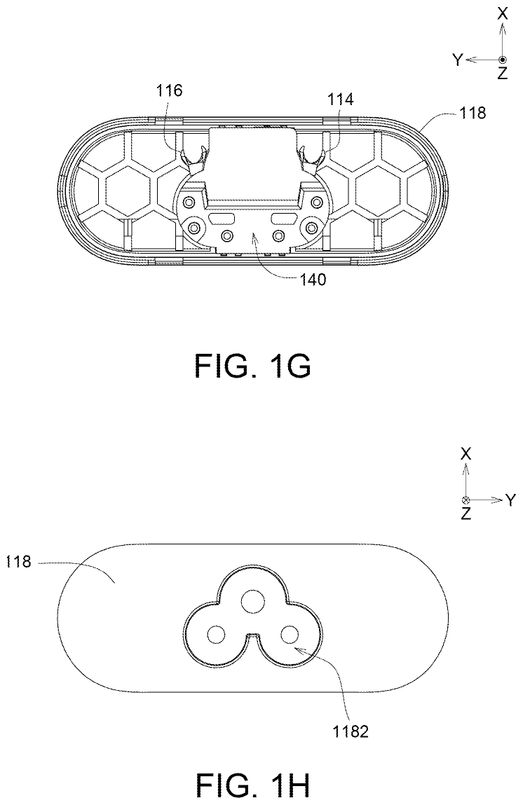

Referring to FIGS. 1A-1H, an exemplary inlet 100 of the disclosure is shown, wherein FIG. 1A is a perspective view of the inlet 100, FIG. 1B is an exploded perspective view of the inlet 100, FIG. 1C is a top view of the inlet 100, FIG. 1D is a bottom view of the inlet 100, FIG. 1E is a left view of the inlet 100, FIG. 1F is a right view of the socket 100, FIG. 1G is a front view of the inlet 100, and FIG. 1H is a rear view of the socket 100. For assisting understanding of the components, a neutral wire 202, a live wire 204, and a jump wire 206 of the charger are also shown in FIGS. 1A and 1B with dotted lines.

The inlet 100 comprises a body 110, a first plate 120, a circuit board assembly 130, and a second plate 140. The first plate 120 is disposed on the body 110. The first plate 120 has a first hole 122. The circuit board assembly 130 is disposed on the first plate 120. The circuit board assembly 130 has a second hole 1322. The second plate 140 is disposed on the circuit board assembly 130. The body 110 has a first pin 112. The first pin 112 penetrates through the first hole 122 and the second hole 1322 and is covered by the second plate 140.

More specifically, the body 110 comprises the first pin 112, a second pin 114, and a third pin 116. The first pin 112, the second pin 114, and the third pin 116 of the body 110 can be a grounding pin, a live pin, and a neutral pin. In some embodiments, the first pin 112 is a grounding pin, the second pin 114 is a live pin, and the third pin 116 is a neutral pin. The second pin 114 can be configured to hold and to be electrically coupled with the live wire 204. The third pin 116 can be configured to hold and to be electrically coupled with the neutral wire 202. The first pin 112, the second pin 114, and the third pin 116 are electrically conductive. In some embodiments, each of the first pin 112, the second pin 114, and the third pin 116 is entirely formed of a conductive material.

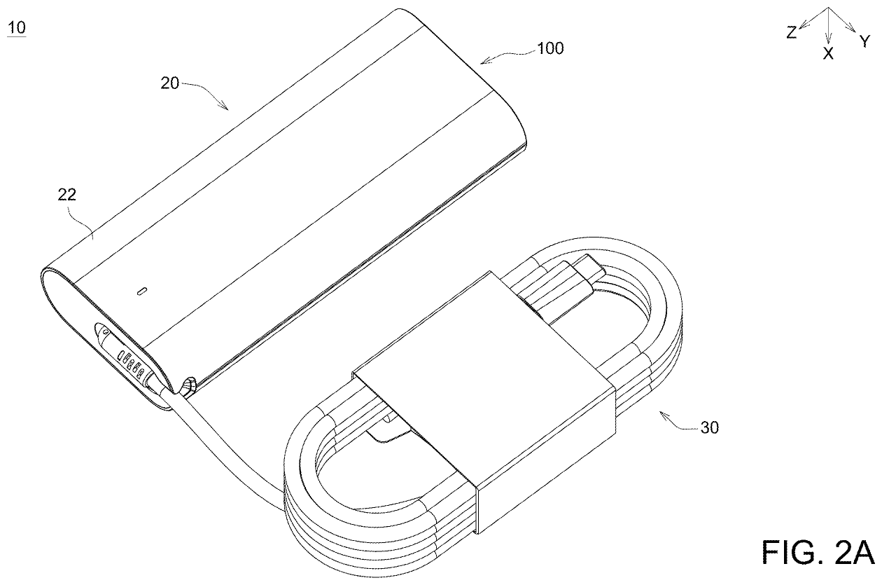

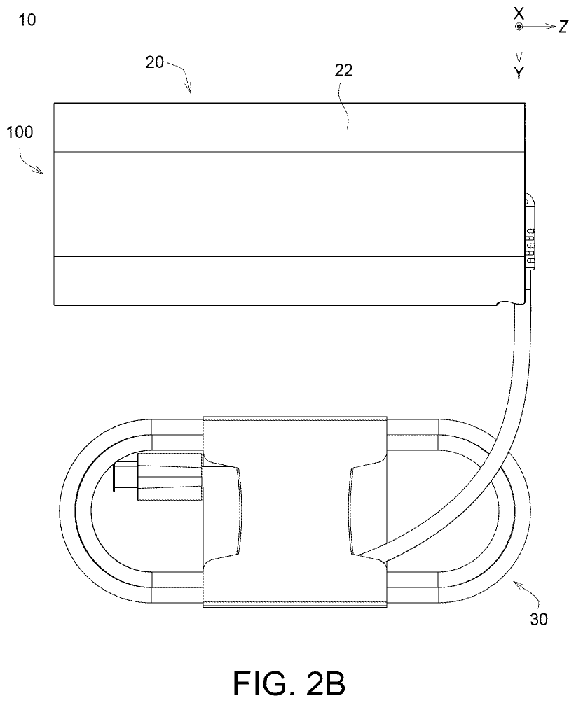

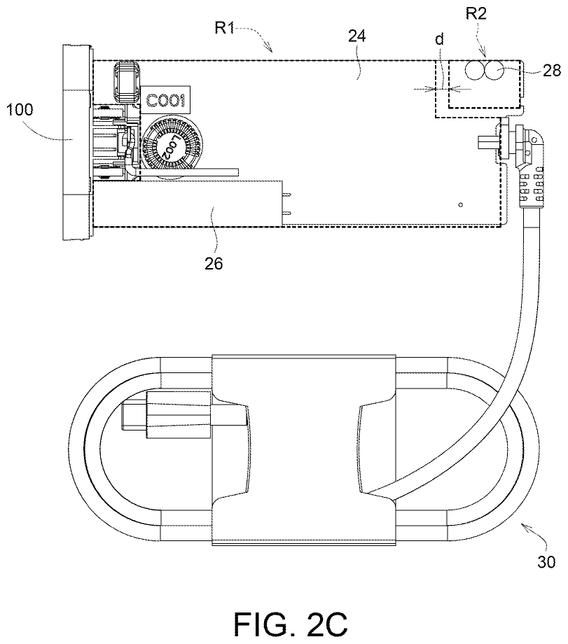

The body 110 can further comprise a cover 118. The first pin 112, the second pin 114, and the third pin 116 are arranged at one side of the cover 118 (+Z side in the drawings). The cover 118 can comprise a cable connecting portion 1182. The cable connecting portion 1182 can be formed at another side of the cover 118 (−Z side in the drawings). The cover 118 can be formed a material the same as a material of a housing (e.g. the housing 22 shown in FIGS. 2A and 2B). According to some embodiments, the cover 118 can have at least one first fastening portion 1184 for connection with the first plate 120.

The first plate 120 can have at least one second fastening portion 124, so as to fasten the first plate 120 onto the body. 110. For example, the first fastening portion 1184 can be a pin, and the second fastening portion 124 can be a hole, but the disclosure is not limited thereto. The first plate 120 can be electrically insulating.

The circuit board assembly 130 can be a printed circuit board assembly. According to some embodiments, the circuit board assembly 130 can comprise a circuit board 132, a gas tube discharge device 134, and a resistor 136. The circuit board 132 has the second hole 1322. The second hole 1322 is configured to receive and to be electrically coupled with the first pin 112. For example, the circuit board 132 can have a conductive portion (shown with a dotted shadow) extending to an edge of the second hole 1322 to be electrically coupled with the first pin 112. The gas tube discharge device 134 and the resistor 136 are disposed on the circuit board 132. In some embodiments, the circuit board 132 further has a third hole 1324. The third hole 1324 is configured to receive and to be electrically coupled with the jump wire 206. Similarly, the circuit board 132 can have a conductive portion (shown with a dotted shadow) extending to an edge of the third hole 1324 to be electrically coupled with the first pin jump wire 206. The gas tube discharge device 134 and the resistor 136 can be disposed between the second hole 1322 and the third hole 1324.

The second plate 140 covers the first pin 112, so as to prevent a shortage due to the a contact between the first pin 112 and a component of the main circuit board assembly (which will be introduced later) when the inlet is installed on the charger. The second plate 140 can be electrically insulating.

For the assembling of the inlet 100, firstly the first plate 120 is assembled to the body 110 and fastened by, for example, the first fastening portion 1184 and the second fastening portion 124. At this time, the second pin 114 and the third pin 116 are covered by the first plate 120, and the first pin 112 passes through the first hole 122 and protrudes outside the first plate 120. Next, the circuit board assembly 130 is assembled in a manner that the first pin 112 further passes through the second hole 1322. Then, a conductive contact (shown with a dotted shadow) between the first pin 112 and the circuit board assembly 130 is formed by, for example, soldering or any other suitable method. Thereafter, the second plate 140 is assembled. The second plate 140 can be fixed to the first plate 120 and/or the body 110 through a mechanical structure, and the disclosure is not limited thereto.

Now referring to FIGS. 2A-2C, an exemplary charger 10 of the disclosure is shown, wherein FIG. 2A is a perspective view of the charger 10, FIG. 2B is a top view of the charger 10, and FIG. 2C is a top view of the charger 10 without a housing.

The charger 10 comprises a charging plug 20. The charging plug 20 comprises a housing 22, a main circuit board assembly 24, and an inlet 100. The housing 22 has an inlet opening, which is fully occupied by the inlet in the drawings. The main circuit board assembly 24 is disposed in the housing 22. The inlet 100 is disposed at the inlet opening. As described above with reference to FIGS. 1A and 1B, the inlet 10 comprises the body 110, the first plate 120, the circuit board assembly 130, and the second plate 140. The body 110 comprises the first pin 112, the second pin 114, and the third pin 116. The first plate 120 is disposed on the body 110. The first plate 120 has the first hole 122. The circuit board assembly 130 is disposed on the first plate 120. The circuit board assembly 130 has the second hole 1322. The second plate 140 is disposed on the circuit board assembly 130. The first pin 112 penetrates through the first hole 122 and the second hole 1322 and covered by the second plate 140. The other details of the inlet 100 are not repeated again.

FIG. 2C exemplarily shows that the main circuit board assembly 24 has a high voltage region R1 and a low voltage region R2 separated from each other. A distance d between the high voltage region R1 and the low voltage region R2 should at least be the safety distance required by national regulations, such as 7 mm. The main circuit board assembly 24 can be a printed circuit board assembly. The main circuit board assembly 24 comprises a component 26 in the high voltage region R1 and a component 28 in the low voltage region R2. It should be understood, however, the disclosure is not limited thereto. The types and numbers of components of the main circuit board assembly 24, as well as the division of the high voltage region R1 and the low voltage region R2, will change depending on the design and actual needs. The disclosure will not focus on and recite the related details. The inlet 100 is arranged in a manner that the second plate 140 faces the inside of the housing 22. As such, the second plate 140 of the inlet 100 can be close to the high voltage region R1, and is electrically coupled to the low voltage region R2 through a jump wire 206. In FIG. 2C, the jump wire 206 and the component in the low voltage region R2 connected with jump wire 206 are not shown, and one skilled in the art should understand that the connection of the jump wire will change depending on the design and actual needs.

In some embodiments, the charger 10 can further comprise a charging cable 30. The charging cable 30 is configured to be coupled to the charging plug 20.

In summary, the components originally arranged in one of the low voltage areas, such as but not limited to a gas tube discharge device and a resistor, are re-organized onto an inlet according to the disclosure. The inlet according to the disclosure further comprises an additional circuit board assembly directly contacting the first pin, and thus the grounding wire used in the conventional chargers can be omitted. As such, one low voltage region, and thus the safe distance (7 mm in typical) related thereto, can be omitted from the charger. Alternatively, at least the volume of a low voltage region can be decreased. As such, a smaller charger can be provided with the inlet according to the disclosure.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An inlet for a charger, comprising:
a body;
a first plate disposed on the body, the first plate having a first hole;
a circuit board assembly disposed on the first plate, the circuit board assembly having a second hole; and
a second plate disposed on the circuit board assembly;
wherein the body has a first pin penetrating through the first hole and the second hole and covered by the second plate.

2. The inlet according to claim 1, wherein the body further comprises a second pin and a third pin, and the first pin, the second pin, and the third pin are electrically conductive.

3. The inlet according to claim 2, wherein the first pin is a grounding pin, the second pin is a live pin, and the third pin is a neutral pin.

4. The inlet according to claim 2, wherein the second pin is configured to hold and to be electrically coupled with a live wire, and the third pin is configured to hold and to be electrically coupled with a neutral wire.

5. The inlet according to claim 2, wherein the body further comprises:
a cover, wherein the first pin, the second pin, and the third pin are arranged at one side of the cover, and the cover comprises a cable connecting portion formed at another side of the cover.

6. The inlet according to claim 5, wherein the cover has at least one first fastening portion, and the first plate has at least one second fastening portion corresponding to the at least one first fastening portion, so as to fasten the first plate onto the body.

7. The inlet according to claim 1, wherein the first plate and the second plate are electrically insulating.

8. The inlet according to claim 1, wherein the circuit board assembly comprises:
a circuit board having the second hole, wherein the second hole is configured to receive and to be electrically coupled with the first pin;
a gas tube discharge device disposed on the circuit board; and
a resistor disposed on the circuit board.

9. The inlet according to claim 8, wherein the circuit board further has a third hole configured to receive and to be electrically coupled with a jump wire, and the gas tube discharge device and the resistor are disposed between the second hole and the third hole.

10. A charger, comprising:
a charging plug, comprising:
a housing having an inlet opening;
a main circuit board assembly disposed in the housing; and
an inlet disposed at the inlet opening, the inlet comprising:
a body;
a first plate disposed on the body, the first plate having a first hole;
a circuit board assembly disposed on the first plate, the circuit board assembly having a second hole; and
a second plate disposed on the circuit board assembly;
wherein the body has a first pin penetrating through the first hole and the second hole and covered by the second plate.

11. The charger according to claim 10, wherein the main circuit board assembly has a high voltage region and a low voltage region separated from each other, and wherein the second plate of the inlet is close to the high voltage region, and is electrically coupled to the low voltage region through a jump wire.

12. The charger according to claim 10, wherein the body further comprises a second pin and a third pin, and the first pin, the second pin, and the third pin are electrically conductive.

13. The charger according to claim 12, wherein the first pin is a grounding pin, the second pin is a live pin, and the third pin is a neutral pin.

14. The charger according to claim 12, wherein the second pin is configured to hold and to be electrically coupled with a live wire, and the third pin is configured to hold and to be electrically coupled with a neutral wire.

15. The charger according to claim 12, wherein the body further comprises:
a cover, wherein the first pin, the second pin, and the third pin are arranged at one side of the cover, and the cover comprises a cable connecting portion formed at another side of the cover.

16. The charger according to claim 15, wherein the cover has at least one first fastening portion, and the first plate has at least one second fastening portion corresponding to the at least one first fastening portion, so as to fasten the first plate onto the body.

17. The charger according to claim 10, wherein the first plate and the second plate are electrically insulating.

18. The charger according to claim 10, wherein the circuit board assembly comprises:
a circuit board having the second hole, wherein the second hole is configured to receive and to be electrically coupled with the first pin;
a gas tube discharge device disposed on the circuit board; and
a resistor disposed on the circuit board.

19. The charger according to claim 18, wherein the circuit board further has a third hole configured to receive and to be electrically coupled with a jump wire, and the gas tube discharge device and the resistor are disposed between the second hole and the third hole.

20. The charger according to claim 10, further comprising:
a charging cable configured to be coupled to the charging plug.
